(19) United States
(12) Patent Application Publication
(10) Pub. No.: US 2026/0163578 A1
(43) Pub. Date: Jun. 11, 2026

(54) SEMICONDUCTOR DEVICE AND MOTOR CONTROL SYSTEM

(71) Applicant: Renesas Electronics Corporation, Tokyo (JP)

(72) Inventors: Akihiro ONO, Tokyo (JP); Motoshige IKEDA, Tokyo (JP); Yutaka WATANABE, Tokyo (JP); Takanobu NIMIYA, Tokyo (JP)

(21) Appl. No.: 19/391,644

(22) Filed: Nov. 17, 2025

(30) Foreign Application Priority Data
Dec. 5, 2024 (JP) 2024-212180

(51) Int. Cl. H03M 1/06; H02P 6/08; H02P 27/08; H03L 7/18

(52) U.S. Cl. CPC H03M 1/0624; H02P 6/08; H02P 27/08; H03L 7/18

(57) ABSTRACT

A semiconductor device includes a timer control circuit (timer) and an AD converter (ADC), and generates a PWM signal by using a periodic signal of the timer on the basis of an ADC output. After receiving an AD conversion start request signal (ADR signal), the ADC starts AD conversion in synchronization with a latest AD synchronization signal. The timer outputs a timer phase signal that is a basis for starting generation of a periodic signal and the ADR signal when a phase-locked loop counter value matches a value of a timer phase register, outputs an AD synchronization phase signal that is a basis for starting generation of the AD synchronization signal when the counter value matches the value of an AD synchronization phase register, and controls a phase difference between the ADR signal and the AD synchronization signal to be constant regardless of activation timing of the device.

### CROSS-REFERENCE TO RELATED APPLICATIONS

The disclosure of Japanese Patent Application No. 2024-212180 filed on December 5, 2024 including the specification, drawings and abstract is incorporated herein by reference in its entirety.

### BACKGROUND

The present invention relates to a semiconductor device, and can be suitably used for, for example, a semiconductor device including an AD converter and a motor control system using the semiconductor device.

### There is disclosed a technique listed below.

Patent Document 1 Japanese Unexamined Patent Application Publication No. 2019-88185

A method for controlling an operation of equipment using a semiconductor device is known. The equipment is, for example, a motor. For example, Patent Document 1 discloses such a control method.

### SUMMARY

In controlling equipment using a semiconductor device including an AD converter for acquiring information related to an operation of the equipment, it is one of problems to improve control accuracy.

Note that other problems and novel features will become apparent from the description of the present specification and the accompanying drawings.

According to one embodiment, a semiconductor device includes a phase-locked loop counter that starts counting with activation of the semiconductor device. The semiconductor device uses a value of the phase-locked loop counter to control the timing of starting generation of various signals such that a phase difference between an AD conversion start request signal and an AD conversion synchronization signal is constant regardless of the timing of activation of the semiconductor device.

According to the one embodiment, in controlling equipment using a semiconductor device including an AD converter for acquiring information related to an operation of the equipment, it is possible to improve control accuracy.

### BRIEF DESCRIPTION OF THE DRAWINGS

FIG. 1 is a diagram illustrating an example of a basic configuration of a motor control system.

FIG. 2 is a diagram illustrating a timing chart of main signals/processing in a semiconductor device.

FIG. 3 is a diagram illustrating a configuration example of a circuit/functional blocks in a main part of the semiconductor device as a reference.

FIG. 4 is a timing chart illustrating an example of an ideal latency Da.

FIG. 5 is a timing chart illustrating a first example of an actual latency Da.

FIG. 6 is a timing chart illustrating a second example of an actual latency Da.

FIG. 7 is a diagram illustrating a configuration example of a circuit/functional blocks in a main part of the semiconductor device according to a first embodiment.

FIG. 8 is a diagram illustrating an example of a timing chart of each signal in the semiconductor device according to the first embodiment.

FIG. 9 is a diagram illustrating a configuration example of a circuit/functional blocks in a main part of a semiconductor device according to a second embodiment.

FIG. 10 is a diagram illustrating an example of a timing chart of each signal in the semiconductor device according to the second embodiment.

### DETAILED DESCRIPTION

Embodiments will now be described below, and first, a basic configuration, function, and operation of a motor control system will be described, and next, the background of the study by the present inventors will be described. Thereafter, embodiments proposed by the present inventors will be described.

Note that, in the present specification, the rotation, the rotation amount, the rotation angle position, the rotation speed, and the like of a rotating body, that is, a rotor in the motor are also simply referred to as the rotation, the rotation amount, the rotation angle position, the rotation speed, and the like of the motor, respectively. In addition, in the present specification, the phases of the various signals are, in principle, relative phases based on the phase of a periodic signal, i.e., a carrier, used for generating a PWM control signal. In addition, in the present specification, the rotation angle position of the rotor is also referred to as a rotor position, and the rotation speed of the rotor is also referred to as a rotor speed. In addition, the same or corresponding components in the embodiments are denoted by the same reference numerals, and repeated description is omitted unless necessary.

### (Basic Configuration and Function/Operation of Motor Control System)

A motor control system in which a controller controls an operation of a motor via a semiconductor device is known. Here, an example of a basic configuration, a function, and an operation of such a motor control system will be described.

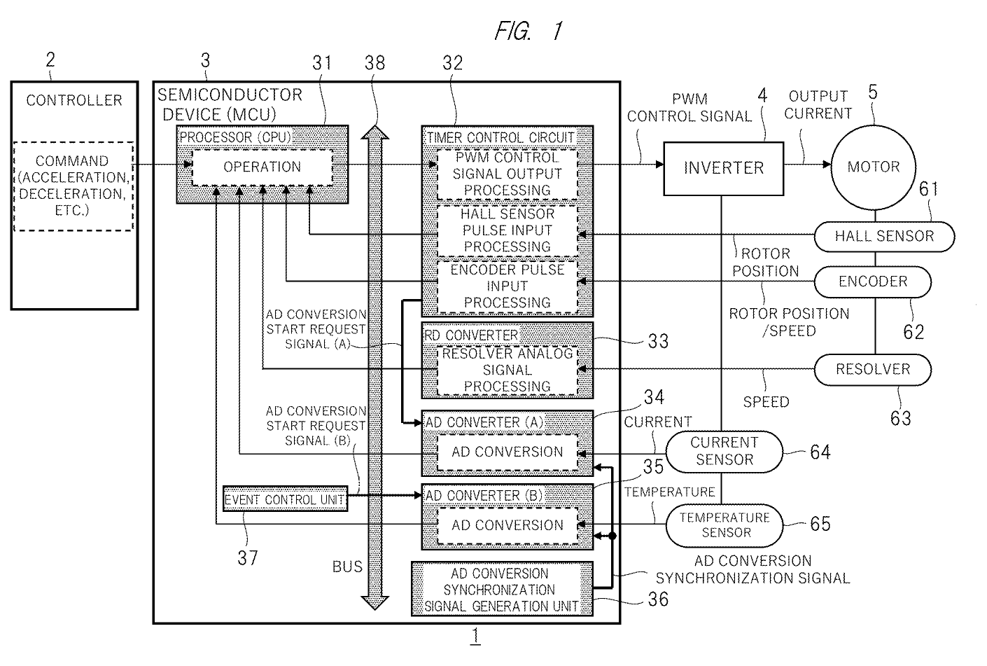

FIG. 1 is a diagram illustrating an example of a basic configuration of the motor control system. As illustrated in FIG. 1, a motor control system 1 includes, for example, a controller 2, a semiconductor device 3, an inverter 4, and a motor 5.

The controller 2 is provided outside the semiconductor device 3, and inputs instruction information indicating an instruction related to the rotation of the motor 5 to the semiconductor device 3. The instruction includes, for example, acceleration, deceleration, and speed maintenance of the rotor in the motor 5. The controller 2 is, for example, a host controller positioned at a higher level with respect to the semiconductor device 3. The semiconductor device 3 generates a pulse width modulation (PWM) control signal on the basis of the input instruction information, and inputs the PWM control signal to the inverter 4. The PWM control signal is also referred to as a PWM signal, a PWM pulse, a PWM control pulse, or the like.

The inverter 4 supplies a current to the motor 5 based on the input PWM control signal. The inverter 4 controls an output current by turning on and off a power switching device by PWM control, for example, and supplies the current to the motor 5. The power switching device is, for example, an insulated gate bipolar transistor (IGBT). The motor 5 is driven according to the supplied current, and the rotation amount, the rotation angle, the rotation speed, and the like of the rotor in the motor 5 are controlled. The motor 5 is, for example, a DC motor.

The motor 5 is provided with a Hall sensor 61, an encoder 62, and a resolver 63. The Hall sensor 61 detects a magnetic field corresponding to the rotor position in the motor 5 and outputs a pulse signal corresponding to the detected magnetic field. The encoder 62 outputs a pulse signal corresponding to the rotor position or the rotor speed in the motor 5. The resolver 63 outputs an analog signal corresponding to the rotor position or the rotor speed of the motor 5.

In addition, the inverter 4 is provided with a current sensor 64 and a temperature sensor 65. The current sensor 64 detects the output current of the inverter 4 and outputs an analog signal corresponding to the detected current value. The temperature sensor 65 detects the temperature of the inverter 4 itself or the ambient temperature of the inverter 4, and outputs an analog signal corresponding to the detected temperature value.

The semiconductor device 3 not only controls the rotation of the motor 5 but also monitors information related to the rotation operation of the motor 5 with high real-time property by using the plurality of sensors described above. The semiconductor device 3 outputs a signal representing the rotor position, the rotor speed, and the like in the motor 5 to the controller 2 as a feedback signal on the basis of the monitored information related to the rotation operation of the motor 5.

A processor (CPU) 31 generates instruction information of a timer control circuit 32 based on the feedback signal and controls the motor 5. The semiconductor device 3 generates a PWM control signal for controlling the output current of the inverter 4 on the basis of the information related to the rotation operation of the motor 5 and the instruction information from the controller 2, and outputs the PWM control signal to the inverter 4. That is, the semiconductor device 3 feedback-controls the motor 5 directly and at high speed. The controller 2 indirectly controls the motor 5 via the semiconductor device 3.

The semiconductor device 3 will be described more specifically below. As illustrated in FIG. 1, the semiconductor device 3 is, for example, a micro controller unit (MCU). The semiconductor device 3 includes, for example, the processor 31, the timer control circuit 32, an RD converter 33, a plurality of AD converters, an AD conversion synchronization signal generation unit 36, an event control unit 37, and a communication bus 38. Here, the plurality of AD converters includes an AD converter (A) 34 and an AD converter (B) 35. The processor 31, the timer control circuit 32, the RD converter 33, the AD converter (A) 34, the AD converter (B) 35, the AD conversion synchronization signal generation unit 36, and the event control unit 37 are electrically connected to the bus 38. The units connected to the bus 38 can exchange information with one another as necessary.

The timer control circuit 32 performs Hall sensor pulse input processing and encoder pulse input processing. The Hall sensor pulse input processing is processing of receiving a pulse signal corresponding to the rotor position from the Hall sensor 61, generating data representing the rotor position on the basis of the pulse signal, and outputting the data to the processor 31. The encoder pulse input processing is processing of receiving a pulse signal corresponding to the rotor position/speed from the encoder 62, generating data representing the rotor position/speed on the basis of the pulse signal, and outputting the data to the processor 31.

The RD converter 33 performs resolver analog signal processing. The resolver analog signal processing is processing of receiving an analog signal that can specify the rotor speed from the resolver 63, generating data representing the rotor speed on the basis of the analog signal, and outputting the data to the processor 31.

The AD converter (A) 34 performs AD conversion (A). The AD conversion (A) is processing of receiving an analog signal corresponding to the current of the inverter 4 from the current sensor 64, converting the analog signal into a digital signal, and outputting data that is the converted digital signal to the processor 31. When an AD conversion start request signal is input from the timer control circuit 32, the AD converter (A) 34 starts the AD conversion (A) according to the AD conversion start request signal.

The AD converter (B) 35 performs AD conversion (B). The AD conversion (B) is processing of receiving an analog signal corresponding to the temperature of the inverter 4 from the temperature sensor 65, converting the analog signal into a digital signal, and outputting data that is the converted digital signal to the processor 31. When an AD conversion start request signal is input from the event control unit 37, the AD converter (B) 35 starts the AD conversion (B) according to the AD conversion start request signal.

The AD conversion synchronization signal generation unit 36 generates an AD conversion synchronization signal and outputs the generated AD conversion synchronization signal to each of the AD converters (A) 34 and (B) 35. The AD conversion synchronization signal is an example of an "AD synchronization signal" in the present application, and is a signal that determines a timing at which the AD converter starts the AD conversion. The AD converter does not start the AD conversion immediately after receiving the AD conversion start request signal, but waits until the "AD synchronization signal" rises, and starts the AD conversion in synchronization with the "AD synchronization signal." Therefore, in general, a time difference, that is, a phase difference occurs between the timing at which the AD conversion start request signal is input and the timing at which the AD conversion is started.

The timer control circuit 32 also performs PWM control signal output processing. In addition, the timer control circuit 32 includes a timer counter as described below, and causes the timer counter to start counting in response to the output of a timer phase signal. Based on the counter value of the timer counter, the timer control circuit 32 generates a periodic signal used for PWM and an AD conversion start request signal for requesting the start of the AD conversion.

The PWM control signal output processing is processing of generating a PWM control signal for PWM control of the output current of the inverter 4 and outputting the generated PWM control signal to the inverter 4. When the inverter 4 is a three-phase inverter, the PWM control signal can be, for example, an on/off signal for each of the U phase, the V phase, and the W phase. The timer counter starts counting when a start trigger is input, and the counter value repeats a change from zero to a predetermined value. In order to generate the PWM control signal, the timer control circuit 32 generates a periodic signal drawn by a temporal change of the counter value of the timer counter, that is, a triangular wave (sawtooth-shaped) signal as a carrier in PWM.

In addition, the timer control circuit 32 generates an AD conversion start request signal (A) in synchronization with the phase of the carrier, that is, at the same cycle as the triangular wave signal, for example, and inputs the AD conversion start request signal (A) to the AD converter (A) 34 connected to the current sensor 64. By inputting the AD conversion start request signal (A) synchronized with the phase of the carrier to the AD converter (A) 34, the output current of the inverter 4 can be monitored at high speed in a relatively short cycle in the semiconductor device 3.

The event control unit 37 generates an AD conversion start request signal (B) as an event, and inputs the AD conversion start request signal (B) to the AD converter (B) 35 connected to the temperature sensor 65. The AD conversion start request signal (B) is generated aperiodically, or is generated with a longer period as compared with the AD conversion start request signal (A). This is because the temperature of the inverter 4 detected by the temperature sensor 65 is less likely to fluctuate abruptly and it is sufficient if it is monitored at a relatively long cycle. When the frequency of AD conversion decreases, power consumption in the AD converter is suppressed, and energy saving can be achieved.

The processor 31 performs an operation. This operation is processing of calculating and obtaining a signal value necessary for the PWM control signal output processing in the timer control circuit 32 based on the input command information and a plurality of pieces of information related to the rotation operation of the motor 5. The processor 31 outputs the signal value obtained by the operation to the timer control circuit 32.

Note that the command indicated by the command information is, for example, acceleration, deceleration, and maintenance of the rotor speed in the motor 5. The information related to the rotation operation of the motor 5 includes data representing the rotor position obtained by the Hall sensor pulse input processing. In addition, the information regarding the rotation operation of the motor 5 also includes data representing the rotor position/speed obtained by the encoder pulse input processing and data representing the rotor speed obtained by the resolver analog signal processing. In addition, the information regarding the rotation operation of the motor 5 also includes data representing the output current of the inverter 4 obtained by the AD conversion (A), data representing the temperature of the inverter 4 obtained by the AD conversion (B), and the like.

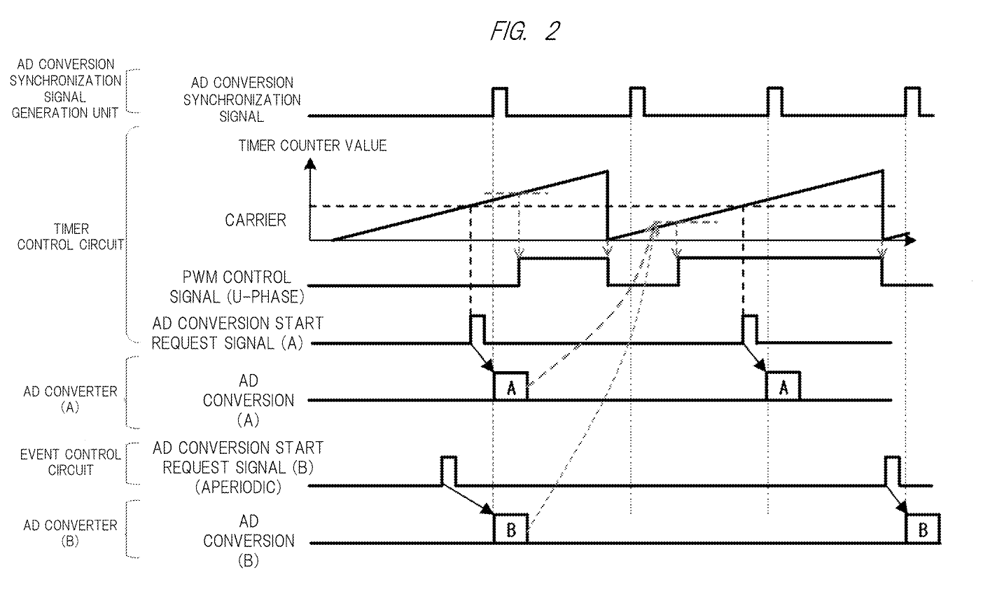

FIG. 2 is a diagram illustrating a timing chart of main signals/processing in the semiconductor device. The timing chart of FIG. 2 illustrates an AD conversion synchronization signal in the AD conversion synchronization signal generation unit 36, and a timer counter value, a PWM control signal, and an AD conversion start request signal (A) in the timer control circuit 32. In addition, the timing chart of FIG. 2 illustrates AD conversion (A) in the AD converter (A) 34, an AD conversion start request signal (B) in the event control unit 37, and AD conversion (B) in the AD converter (B) 35. Note that, here, the inverter 4 is a three-phase inverter, and a U-phase on/off signal in the inverter 4 is illustrated as a representative example of the PWM control signal.

The timer control circuit 32 includes a comparator, which is not illustrated. The PWM control signal can be obtained as an output of the comparator with one input in the comparator as a timer counter value of a carrier and the other input as a determination voltage value. This determination voltage value is obtained by an operation in the processor 31. Here, when the timer counter value of the carrier is greater than or equal to the determination voltage value, the PWM control signal becomes high (High), and when the timer counter value of the carrier is less than the determination voltage value, the PWM control signal becomes low (Low).

After receiving the AD conversion start request signal (A), the AD converter (A) 34 starts the AD conversion (A) in synchronization with the latest AD conversion synchronization signal. Similarly, after receiving the AD conversion start request signal (B), the AD converter (B) 35 starts the AD conversion (B) in synchronization with the latest AD conversion synchronization signal.

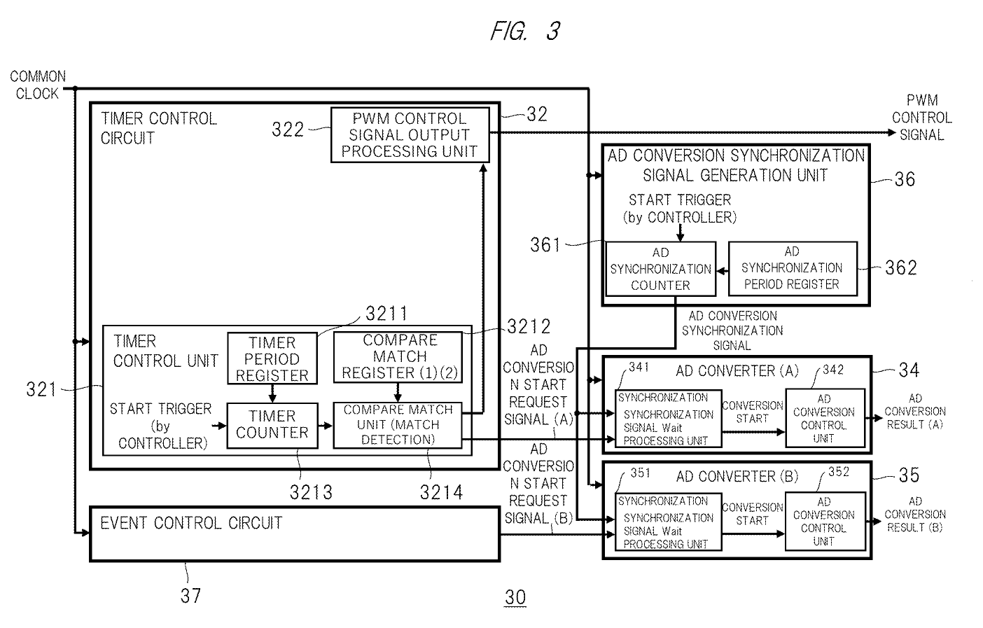

FIG. 3 is a diagram illustrating a configuration example of a circuit/functional blocks in a main part of the semiconductor device as a reference. As illustrated in FIG. 3, a common clock is input to a main part 30 of the semiconductor device 3, and processing is executed in synchronization with the common clock.

A circuit/functional blocks constituting the timer control circuit 32 will be described. As illustrated in FIG. 3, the timer control circuit 32 includes a timer control unit 321 and a PWM control signal output processing unit 322 as a main circuit/functional blocks. The timer control unit 321 includes a timer period register 3211, a compare match register 3212, a timer counter 3213, and a compare match unit 3214. The compare match register 3212 includes a compare match register (1) and a compare match register (2).

When receiving the start trigger, the timer counter 3213 starts counting. In the semiconductor device 3, the controller 2 outputs a start trigger to the timer counter 3213. A reset value, which is a counter value for resetting the timer counter 3213, is set in the timer period register 3211. When the counter value reaches the reset value, which is a setting value of the timer period register 3211, the timer counter 3213 returns the counter value to zero and restarts counting. That is, the timer counter 3213 repeats the operation of counting the count value from zero to the reset value with a constant cycle after the start trigger signal is received for activation.

A counter value (A) that determines a timing at which the compare match unit 3214 outputs the AD conversion start request signal (A) is set in the compare match register (1). In addition, a counter value (B) that determines the above-described determination voltage value necessary for generating the PWM control signal is set in the compare match register (2). The counter value (B) is set every cycle by the controller 2. When detecting that the value of the timer counter 3213 matches the setting value of the compare match register (1), the compare match unit 3214 outputs the AD conversion start request signal (A) to the AD converter (A) 34. In addition, when detecting that the value of the timer counter 3213 matches the setting value of the compare match register (2), the compare match unit 3214 outputs a signal indicating the above-described determination voltage value to the PWM control signal output processing unit 322.

A circuit/functional blocks constituting the AD conversion synchronization signal generation unit 36 will be described. As illustrated in FIG. 3, the AD conversion synchronization signal generation unit 36 includes an AD synchronization counter 361 and an AD synchronization period register 362. Upon receiving the start trigger, the AD synchronization counter 361 starts counting. In the semiconductor device 3, the controller 2 outputs a start trigger signal to the AD synchronization counter 361. A reset value, which is a counter value for resetting the AD synchronization counter 361, is set in the AD synchronization period register 362. When the counter value reaches the reset value set in the AD synchronization period register 362, the AD synchronization counter 361 outputs an AD conversion synchronization signal, returns the counter value to zero, and restarts counting. That is, in response to the output of an AD synchronization phase signal, the AD conversion synchronization signal generation unit 36 in the timer control circuit 32 starts generating an AD conversion synchronization signal corresponding to a specific phase in the carrier that is a periodic signal. Note that this specific phase is a relative phase when a phase corresponding to a period of a carrier that is a periodic signal is used as a reference.

A circuit/functional blocks constituting the AD converter (A) 34 will be described. As illustrated in FIG. 3, the AD converter (A) 34 includes a synchronization signal Wait processing unit 341 and an AD conversion control unit 342. The synchronization signal Wait processing unit 341 receives the AD conversion synchronization signal output from the AD synchronization counter 361. Upon receiving the AD conversion start request signal (A) from the compare match unit 3214, the synchronization signal Wait processing unit 341 waits until receiving the AD conversion synchronization signal. When receiving the AD conversion start request signal (A) and then receiving the AD conversion synchronization signal, the synchronization signal Wait processing unit 341 transmits a conversion start signal to the AD conversion control unit 342 in synchronization with the AD conversion synchronization signal.

The AD conversion control unit 342 receives the conversion start signal, starts the AD conversion (A), and outputs an AD conversion result (A). Here, the AD conversion control unit 342 samples an analog signal, which is an output of the current sensor 64, converts the analog signal into a digital signal, and outputs the converted digital signal to the processor 31 as an AD conversion result (A).

A circuit/functional blocks constituting the AD converter (B) 35 will be described. As illustrated in FIG. 3, the AD converter (B) 35 includes a synchronization signal Wait processing unit 351 and an AD conversion control unit 352. The synchronization signal Wait processing unit 351 receives the AD conversion synchronization signal output from the AD synchronization counter 361. Upon receiving the AD conversion start request signal (B) from the event control unit 37, the synchronization signal Wait processing unit 351 waits until receiving the AD conversion synchronization signal. When receiving the AD conversion start request signal (B) and then receiving the AD conversion synchronization signal, the synchronization signal Wait processing unit 351 transmits a conversion start signal to the AD conversion control unit 342 in synchronization with the AD conversion synchronization signal.

The AD conversion control unit 352 receives the conversion start signal, starts the AD conversion (B), and outputs an AD conversion result (B). Here, the AD conversion control unit 352 samples an analog signal, which is an output of the temperature sensor 65, converts the analog signal into a digital signal, and outputs the converted digital signal to the processor 31 as an AD conversion result (B).

### (Background of Study by the Present Inventors)

Hereinafter, the background of the study by the present inventors will be described, and first, the technical background of the motor control system will be described, and then the problems found by the present inventors will be described.

### <Technical Background of Motor Control System>

In recent years, a semiconductor device used in an equipment control system has been enhanced in performance/multi-functionality. For example, a semiconductor device for a motor control system acquires a plurality of pieces of information related to the rotation operation of a motor in accordance with enhancement in performance/multi-functionality thereof, and performs PWM control of an inverter that supplies a current to the motor on the basis of the information. Such PWM control of the inverter by the semiconductor device implements feedback control of the motor. In addition, in recent motor control, various types of information used for feedback control are required for high-speed rotation, high efficiency, and low noise of a motor, and accuracy is further required.

Under such circumstances, the information used for feedback control of the motor is not limited to conventional information such as the rotation position and the rotation speed of the motor obtained from a Hall sensor, an encoder, or the like. The information used for feedback control of the motor includes, in addition to the conventional information described above, information such as a current value and a temperature value of the inverter obtained from a current sensor, a temperature sensor, and the like provided in the inverter that drives the motor. The semiconductor device needs to receive such various types of information as analog signals and perform observation at an extremely high speed, for example, substantially in real time. Therefore, a semiconductor device often includes a plurality of AD converters.

However, the AD converter generates power supply noise when starting the AD conversion. More specifically, the AD conversion is processing of sampling an analog signal a plurality of times, storing an analog charge amount, and converting the analog charge amount into a digital value. In particular, since the AD converter consumes a large amount of power when starting the processing of converting the analog charge amount into the digital value, power supply noise is likely to occur at this timing.

In a case where there is a plurality of AD converters, noise interference occurs in which power supply noise interferes during AD conversion, which causes deterioration in accuracy of AD conversion. For example, when the AD converter (B) starts the AD conversion (B) while the AD converter (A) is performing the AD conversion (A), the power supply noise generated in the AD conversion (B) interferes with the AD conversion (A), and the accuracy of the AD conversion (A) deteriorates.

Therefore, in a semiconductor device including a plurality of AD converters, in order to suppress deterioration of accuracy of AD conversion, a start timing of AD conversion is controlled such that each AD converter starts AD conversion at a timing at which noise interference hardly occurs.

For example, as illustrated in FIG. 2, the AD conversion synchronization signal generation unit generates an AD conversion synchronization signal synchronized with a periodic signal used for generating a PWM control signal in the timer control circuit, that is, a carrier. The AD converter (A) and the AD converter (B) included in the semiconductor device each start AD conversion in synchronization with the latest AD conversion synchronization signal after receiving the AD conversion start request signal. As described above, noise interference can be suppressed by synchronizing the start timing of AD conversion with the AD conversion synchronization signal.

### <Problems Found by the Present Inventors>

Meanwhile, a host controller that controls a semiconductor device generally outputs a start trigger for starting counting to each of a timer counter of a timer control circuit and an AD synchronization counter of an AD conversion synchronization signal generation unit. The start trigger is issued at different timings for each activation of the controller or each activation of the semiconductor device. Therefore, the delay amount from the timing at which the timer counter starts counting to the timing at which the AD synchronization counter starts counting varies every time the controller or the semiconductor device is activated. Here, a delay amount from the timing at which the timer counter starts counting to the timing at which the AD synchronization counter starts counting is referred to as a latency Dt. Note that the latency can also be said to be a relative phase difference in a case where a phase corresponding to a period of a carrier that is a periodic signal is used as a reference.

The latency Dt is different for each activation of the controller or the semiconductor device. Therefore, a delay amount from when the AD conversion start request signal (A) is issued from the timer control circuit to when the AD converter (A) starts AD conversion also varies. Here, a delay amount from when the AD conversion start request signal (A) is issued to when the AD converter (A) starts AD conversion is referred to as a latency Da.

When the latency Da varies, an error occurs in the AD conversion result of the current value of the inverter. Then, the current value including the error is fed back to the processor. Then, the duty of the PWM control signal obtained by an operation by the processor also varies. When the duty of the PWM control signal varies, the accuracy of the control of the current output from the inverter deteriorates, and finally, the accuracy of the control of the motor deteriorates. This point will be described in more detail with reference to the drawings.

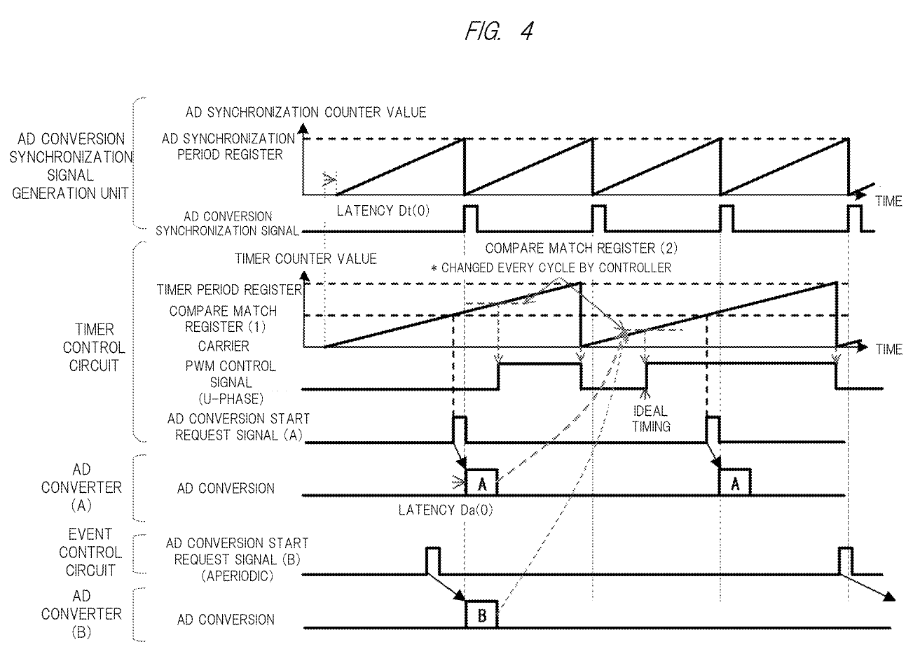

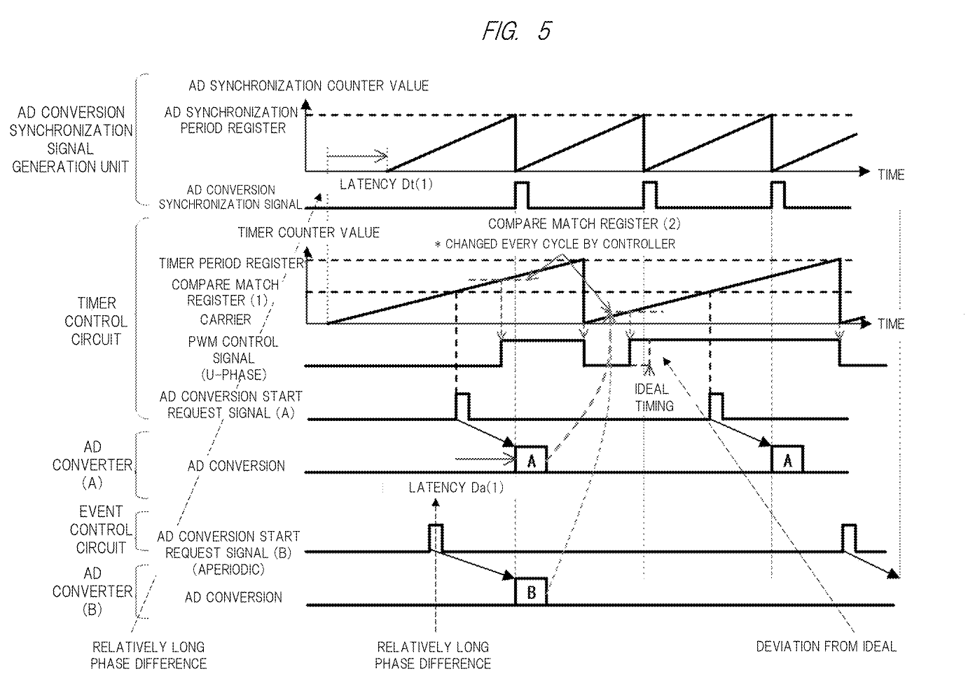

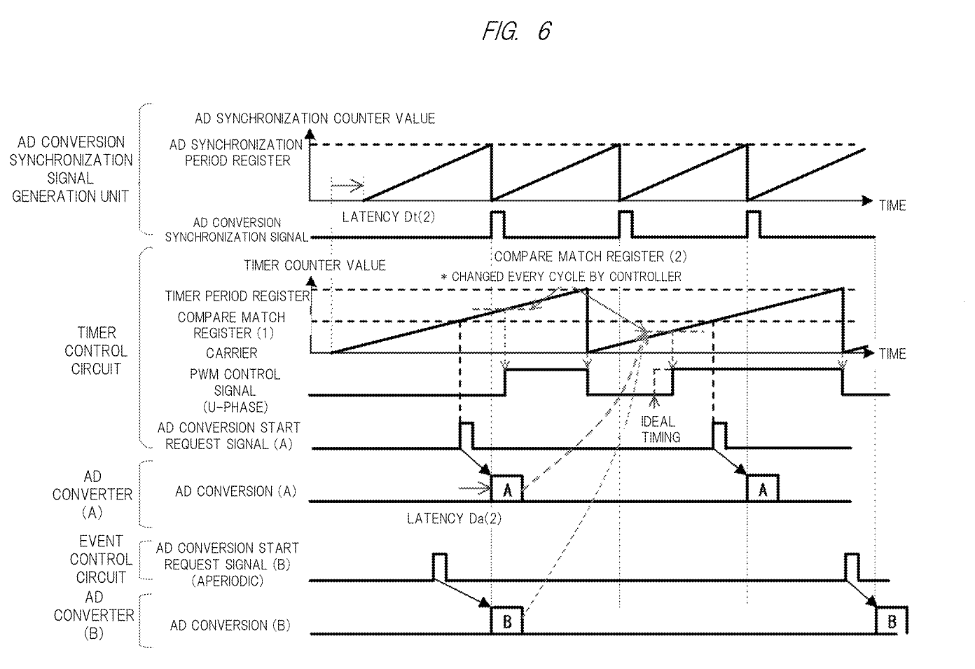

FIG. 4 is a timing chart illustrating an example of an ideal latency Da (ideal case). FIG. 5 is a timing chart illustrating a first example of an actual latency Da (actual case 1). FIG. 6 is a timing chart illustrating a second example of an actual latency Da (actual case 2).

An ideal operation of the AD converter is to operate so as to minimize the latency Da, that is, to start AD conversion immediately after receiving the AD conversion start request signal. Therefore, for example, as illustrated in FIG. 4, in the case of the AD converter (A), ideally, latency Da(0) in which the latency Da is a minimum value is taken, and the AD conversion is started immediately after the AD conversion start request signal is received. In order to implement such an operation, the latency Dt needs to hold latency Dt(0) that takes the latency Da(0) in which the latency Da is a minimum value. When the AD converter performs an ideal operation, the operation in the processor is appropriately performed, and the PWM control signal is also turned on and off at an ideal timing.

However, in practice, the latency Dt varies depending on the activation timing of the semiconductor device. For example, as illustrated in FIG. 5, in some cases, the latency Dt is relatively long latency Dt(1). Then, the latency Da takes longer latency Da(1), and the timing of turning on and off the PWM control signal is also deviated from the ideal. In addition, for example, as illustrated in FIG. 6, the latency Dt becomes relatively short latency Dt(2) in some cases. Then, the latency Da takes short latency Da(2), which is not a minimum value, and the timing of turning on and off the PWM control signal is also deviated from the ideal.

During the research and development of the semiconductor device, the present inventors have found a problem that the latency Da varies every time the semiconductor device is activated and as a result, the accuracy of the control of the motor deteriorates as described above.

### (Semiconductor Device Proposed by the Present Inventors)

Hereinafter, embodiments of the semiconductor device proposed by the present inventors in order to solve the above problems will be described. Note that matters other than the matters described below regarding the configuration, function, operation, and the like of the semiconductor device according to the embodiments are substantially the same as those in the case of the semiconductor device serving as the reference described above.

### <First Embodiment>

A semiconductor device according to the first embodiment includes a phase-locked loop counter that starts counting with activation of the semiconductor device. The semiconductor device uses a value of the phase-locked loop counter to control the timing of starting generation of various signals such that a phase difference between an AD conversion start request signal and an AD conversion synchronization signal is constant regardless of the timing of activation of the semiconductor device. More specific description is given below.

According to the first embodiment, the semiconductor device includes a timer control circuit and an AD converter connected to a sensor that obtains information related to an operation of equipment that is a control target. The semiconductor device generates a PWM control signal for controlling the equipment by using a periodic signal in the timer control circuit based on an output of the AD converter. After receiving an AD conversion start request signal, the AD converter starts the AD conversion in synchronization with a latest AD conversion synchronization signal.

The timer control circuit includes a phase-locked loop counter that starts counting with activation of the semiconductor device, a timer phase register, and an AD synchronization phase register. The timer control circuit executes processing of outputting a timer phase signal that is a basis for starting generation of a periodic signal and an AD conversion start request signal at a timing when a value of the phase-locked loop counter and a setting value of the timer phase register match. In addition, the timer control circuit executes processing of outputting an AD synchronization phase signal that is a basis for starting generation of an AD conversion synchronization signal at a timing when a counter value of the phase-locked loop counter and a setting value of the AD synchronization phase register match. By executing the above processing, the timer control circuit performs control such that the phase difference between the AD conversion start request signal and the AD conversion synchronization signal is constant regardless of the timing of activation of the semiconductor device.

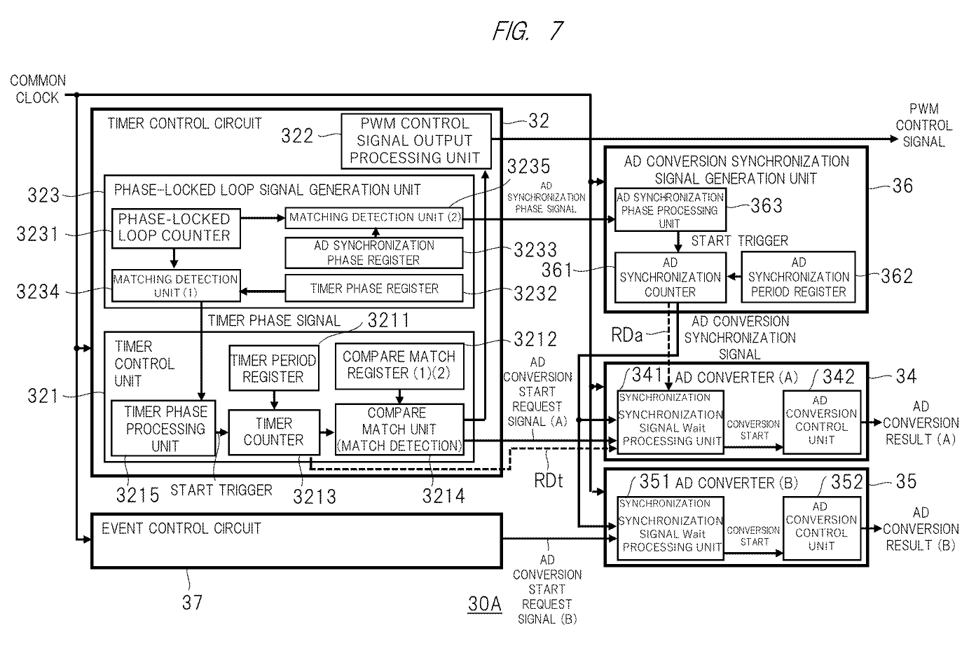

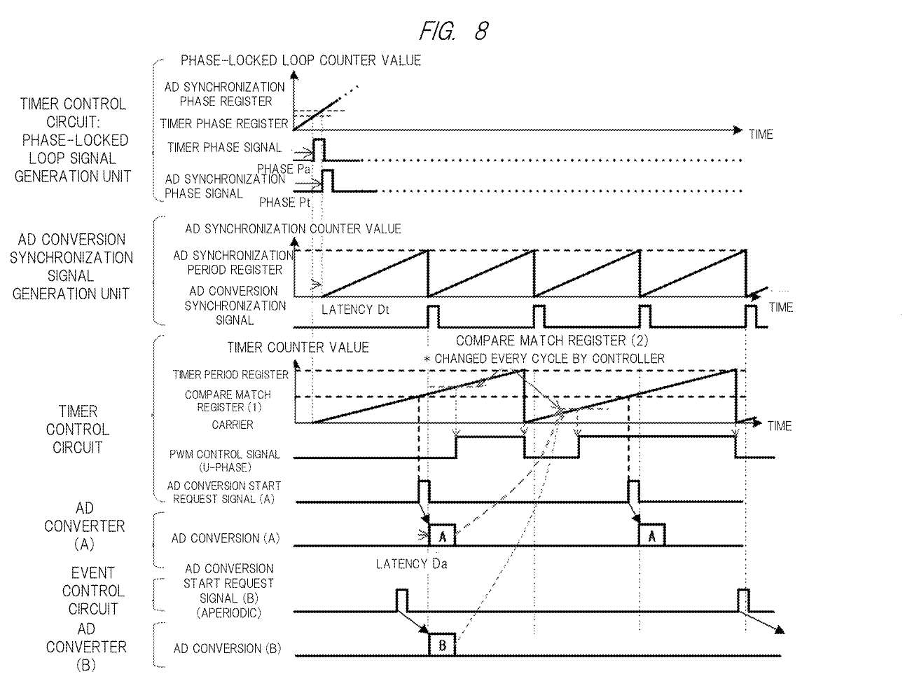

FIG. 7 is a diagram illustrating a configuration example of a circuit/functional blocks in a main part of the semiconductor device according to the first embodiment. In addition, FIG. 8 is a diagram illustrating an example of a timing chart of each signal in the semiconductor device according to the first embodiment.

As illustrated in FIG. 7, a main part 30A of the semiconductor device according to the first embodiment is different from the main part 30 of the semiconductor device as the reference described above in that the timer control circuit 32 further includes a phase-locked loop signal generation unit 323. In addition, the timer control unit 321 further includes a timer phase processing unit 3215, and the AD conversion synchronization signal generation unit 36 further includes an AD synchronization phase processing unit 363.

The phase-locked loop signal generation unit 323 includes a phase-locked loop counter 3231, a timer phase register 3232, an AD synchronization phase register 3233, a matching detection unit (1) 3234, and a matching detection unit (2) 3235. Note that the timer phase register 3232 and the AD synchronization phase register 3233 may be common.

The phase-locked loop counter 3231 starts counting as the semiconductor device is activated. In the timer phase register 3232, a counter value that determines a timing at which the timer phase signal is output is set. The timer phase signal is a signal that is a basis for causing the timer counter 3213 to start counting. A counter value that determines a timing at which the AD synchronization phase signal is output is set in the AD synchronization phase register 3233. The AD synchronization phase signal is a signal that is a basis for causing the AD synchronization counter 361 to start counting.

The matching detection unit (1) 3234 detects whether or not the counter value of the phase-locked loop counter 3231 matches the setting counter value of the timer phase register 3232. Upon detecting matching, the matching detection unit (1) 3234 outputs a timer phase signal to the timer phase processing unit 3215 in a phase Pa corresponding to the setting counter value of the timer phase register 3232 as illustrated in FIG. 8. Note that the phase Pa is a relative phase based on a phase of a carrier that is a periodic signal. The timer phase processing unit 3215 sends a start trigger to the timer counter 3213 according to the input timer phase signal. The timer counter 3213 receives the start trigger and starts counting.

In addition, the matching detection unit (2) 3235 detects whether or not the counter value of the phase-locked loop counter 3231 matches the setting counter value of the AD synchronization phase register 3233. Upon detecting matching, the matching detection unit (2) 3235 outputs the AD synchronization phase signal to the AD synchronization phase processing unit 363 in a phase Pt corresponding to the setting value of the AD synchronization phase register 3233 as illustrated in FIG. 8. Note that the phase Pt is a relative phase based on a phase of a carrier that is a periodic signal. The AD synchronization phase processing unit 363 sends a start trigger to the AD synchronization counter 361 according to the input AD synchronization phase signal. Upon receiving the start trigger, the AD synchronization counter 361 starts counting.

The operation of each unit in the timer control circuit 32 described above makes the latency Dt constant. The latency Dt is a phase difference between a timing at which the timer counter 3213 starts counting and a timing at which the AD synchronization counter 361 starts counting. As the latency Dt becomes constant, the latency Da also becomes constant. The latency Da is a phase difference that is a delay amount from when the AD conversion start request signal (A) is issued until the AD converter (A) 34 starts the AD conversion.

Note that at least one of the timer phase register 3232 and the AD synchronization phase register 3233 may be configured such that a user can set a desired setting value. In this case, the user can set the phase difference between the AD conversion start request signal and the AD conversion synchronization signal (AD synchronization signal) to be a phase difference considered to be convenient in design or implementation.

Alternatively, in at least one of the timer phase register 3232 and the AD synchronization phase register 3233, a specific setting value may be set in advance such that the phase difference between the AD conversion start request signal and the AD conversion synchronization signal becomes a specific phase difference. In this case, the specific setting value is preferably such a value that the specific phase difference described above is a minimum value in design or implementation.

The setting value of each register may be set by the user via the controller, or may be set via a computer connected by the user to the semiconductor device. Alternatively, the setting value of each register may be automatically set by the controller or the computer connected to the semiconductor device executing a program.

As described above, according to the first embodiment, regardless of the activation timing of the semiconductor device, the phase difference between the AD conversion start request signal and the AD conversion synchronization signal becomes constant with respect to the carrier for PWM control, which is a periodic signal. Therefore, by using the semiconductor device including the AD converter, it is possible to improve the control accuracy when the information related to the rotation operation of the motor is acquired by the AD converter and the motor is controlled.

In addition, according to the first embodiment, the phase difference between the AD conversion start request signal and the AD conversion synchronization signal can be brought close to a minimum value. As a result, the control accuracy of the motor 5 as control target equipment can be further improved.

### <Modification of First Embodiment>

Meanwhile, in an actual circuit, an output delay RDt occurs until the AD conversion start request signal (A) is output from the timer counter 3213 to the AD converter (A) 34. Similarly, an output delay RDa occurs until the AD conversion synchronization signal is output from the AD synchronization counter 361 to the

AD converter (A) 34. Then, there may be a case where the output delay RDt and the output delay RDa are different due to a difference in a path on a circuit, variations in characteristics of circuit elements, and the like. In this case, even when the latency Dt is small, the wait time in the synchronization signal Wait processing unit 341 may become long due to the difference between the output delay RDt and the output delay RDa, and the latency Da may become large.

In view of the above circumstances, it is significant that the timer phase register 3232 and the AD synchronization phase register 3233 are separated and separate counter values can be set to the respective registers. When separate counter values can be set to the timer phase register 3232 and the AD synchronization phase register 3233, the phase difference between the AD synchronization phase signal and the AD conversion start request signal can be controlled. That is, the difference in output delay described above can be canceled, and the wait time in the synchronization signal Wait processing unit 341 can be shortened. As a result, the latency Da can be set to a minimum value, that is, Da(0) of the ideal case illustrated in FIG. 4.

Note that, in the above-described embodiments, the phase difference between the AD synchronization phase signal and the AD conversion start request signal is controlled by adjusting the setting values of the timer phase register 3232 and the AD synchronization phase register 3233. Then, such control enables minimization of the latency Da. However, the phase difference between the AD synchronization phase signal and the AD conversion start request signal may be controlled by adding the setting value of the AD synchronization phase register 3233 to the setting value of the compare match register 3212 of the timer control unit 321. Such control can also minimize the latency Da.

### <Second Embodiment>

A circuit of an AD conversion control unit that controls a timing to start AD conversion in an AD converter may have a lower operation speed than other circuits. Therefore, a configuration may be adopted in which a common clock is frequency-divided and a frequency-divided clock is supplied to an AD conversion control unit. In the case of such a configuration, a phase Dd of the frequency-divided clock at the time of activation of a frequency dividing circuit affects a variation in accuracy of AD conversion. Note that the phase Dd is a relative phase based on a phase of a carrier that is a periodic signal. Even in such a case, a semiconductor device according to the second embodiment makes a latency Da, that is, a phase difference between an AD conversion start request signal and an AD conversion synchronization signal constant regardless of the activation timing of the semiconductor device.

The semiconductor device according to the second embodiment includes a frequency dividing circuit that frequency-divides the common clock to generate a frequency-divided clock and outputs the frequency-divided clock to an AD converter. The AD converter starts AD conversion in synchronization with the frequency-divided clock. The semiconductor device according to the second embodiment controls the phase of the frequency-divided clock output from the frequency dividing circuit such that the latency Da is constant regardless of the timing of activation of the semiconductor device.

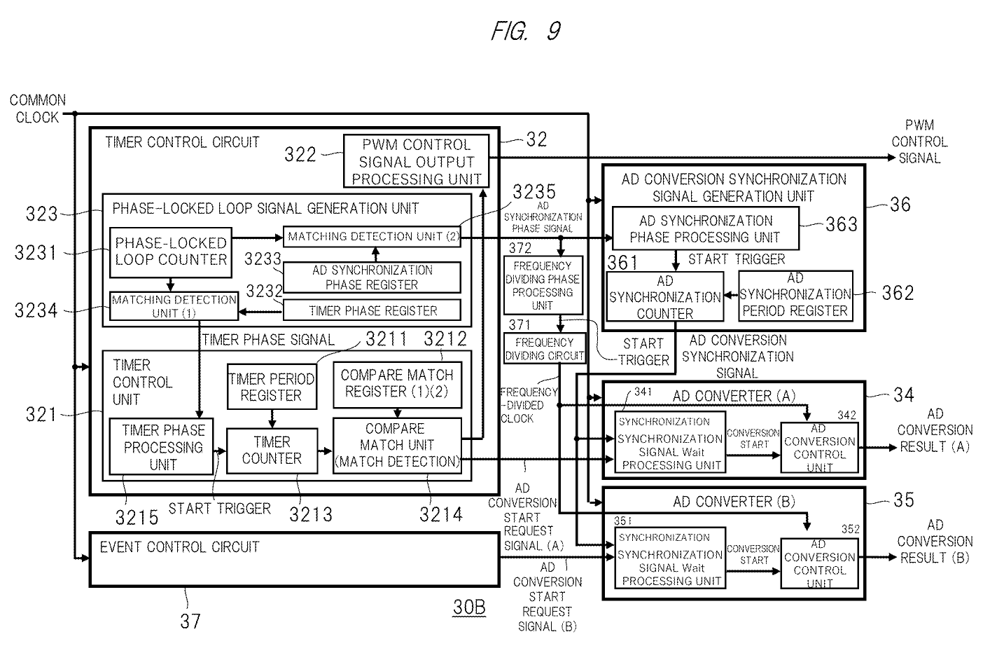

FIG. 9 is a diagram illustrating a configuration example of a circuit/functional blocks in a main part of the semiconductor device according to the second embodiment. As illustrated in FIG. 9, a main part 30B of the semiconductor device according to the second embodiment further includes a frequency dividing circuit 371 and a frequency dividing phase processing unit 372 as compared with the semiconductor device according to the first embodiment. A common clock is input to the semiconductor device in order to synchronize the operation of each unit. The frequency dividing circuit 371 frequency-divides the common clock to generate a frequency-divided clock, and outputs the frequency-divided clock to each of an AD conversion control unit 342 of an AD converter (A) 34 and an AD conversion control unit 352 of an AD converter (B). The frequency dividing phase processing unit 372 adjusts the phase with respect to the frequency dividing circuit 371, that is, the phase of the frequency-divided clock. The frequency dividing phase processing unit 372 adjusts the phase of the frequency-divided clock to make the phase of the frequency-divided clock constant with respect to a timer counter 3213 and an AD synchronization counter 361.

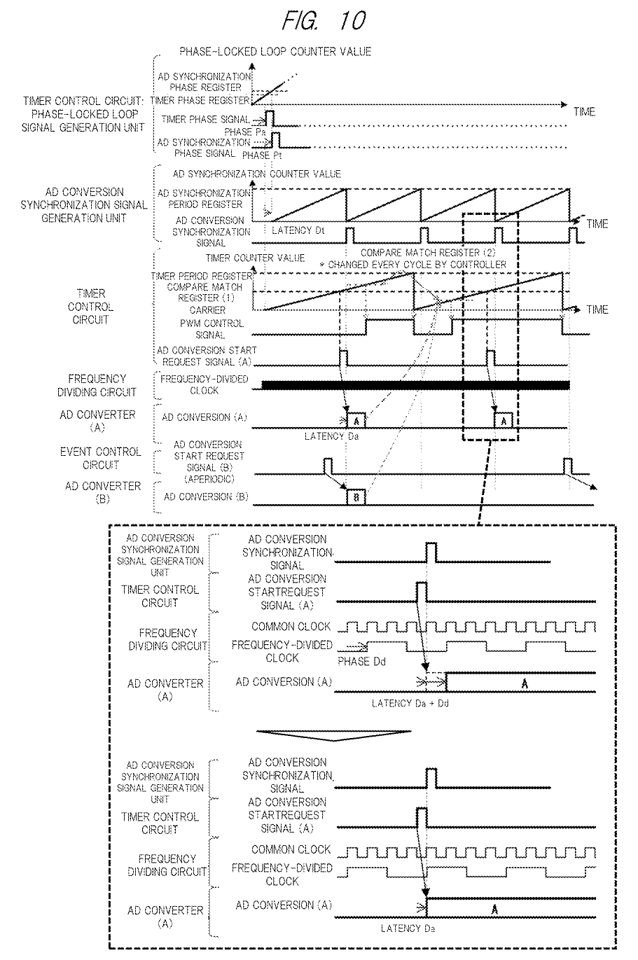

FIG. 10 is a diagram illustrating an example of a timing chart of each signal in the semiconductor device according to the second embodiment. In the semiconductor device according to the second embodiment, as illustrated in FIG. 10, the latency Dt corresponding to the phase difference between a phase Pa of a timer phase signal and a phase Pt of an AD synchronization phase signal occurs. In addition, a latency Da corresponding to a phase difference from when the AD converter (A) receives the AD conversion start request signal (A) to when the AD converter (A) receives an AD conversion synchronization signal also occurs.

On the lower side of FIG. 10, an enlarged view of the AD conversion synchronization signal, the AD conversion start request signal (A), the common clock, the frequency-divided clock, and on/off of the AD conversion in the AD converter (A) is illustrated. In addition, in this enlarged view, the frequency-divided clock and the timing to start AD conversion of the AD converter (A) 34 are illustrated for each case before and after application of phase adjustment of the frequency-divided clock by the frequency dividing phase processing unit 372. The upper part of the enlarged view of the timing chart is a chart before the phase adjustment of the frequency-divided clock is applied, and the lower part is a chart after the phase adjustment of the frequency-divided clock is applied.

As can be understood from this enlarged view, the latency, which is the phase difference between the AD conversion start request signal (A) and the frequency-divided clock as the AD conversion synchronization signal, corresponds to a phase Dd. Then, a latency Dd corresponding to the phase Dd is constant regardless of the activation timing of the semiconductor device. That is, even when the AD conversion is started in synchronization with the frequency-divided clock, the latency Dd can be made constant regardless of the activation timing of the semiconductor device.

As a result, the AD conversion synchronization signal holds a constant phase difference with respect to the carrier for PWM control generated in the timer control circuit 32. Then, the phase difference between the timing at which the PWM control signal is generated and the timing at which the AD conversion is started does not vary with each activation of the semiconductor device according to the second embodiment. As a result, the phase difference between the timing at which the PWM control signal is generated and the timing at which the output of the AD converter (A) is input to the processor 31 becomes constant. When the processor 31 performs the operation for generating the PWM control signal based on the output of the AD converter, the output of the AD converter corresponds to the output of the sensor in the same phase. Therefore, the degree of real-time property does not vary, and the control accuracy is improved.

By the way, attention is paid to the latency from when the AD conversion (A) receives the AD conversion start request signal (A) to when the AD conversion (A) is started before the application of the phase adjustment of the frequency-divided clock. As understood from the upper chart of the enlarged view, the latency of interest is the latency Da + Dd obtained by adding the phase Dd of the frequency-divided clock to the latency Da. That is, the phase Dd of the frequency-divided clock is always added to the latency from when the AD conversion (A) receives the AD conversion start request signal (A) to when the AD conversion (A) is started.

On the other hand, after the phase adjustment of the frequency-divided clock is applied, as understood from the lower chart of the enlarged view, the latency of interest is the latency Da only. That is, since the phase Dd of the frequency-divided clock is adjusted to zero, the latency from when the AD conversion (A) receives the AD conversion start request signal (A) to when the AD conversion (A) is started is suppressed to the latency Da, which is a minimum value. Therefore, when the phase adjustment of the frequency-divided clock is applied, the accuracy of the conversion result of the AD conversion (A) is further improved, the control accuracy of the inverter 4 is improved, and the control accuracy of the motor 5 is finally improved.

Note that at least one of the phase adjustment amounts of the timer phase register 3232, the AD synchronization phase register 3233, and the frequency dividing phase processing unit 372 may be configured such that a desired setting value can be set by the user. In this case, the user can set the phase difference between the AD conversion start request signal and the frequency-divided clock (AD synchronization signal) to be a phase difference considered to be convenient in design or implementation.

Alternatively, specific setting values may be set in advance for one or more of the timer phase register 3232, the AD synchronization phase register 3233, and the frequency dividing phase processing unit 372 (phase adjustment amount) such that the above phase difference becomes a specific phase difference. In this case, the specific setting value is preferably such a value that the specific phase difference described above is a minimum value in design or implementation.

A desired setting value is configured to be set such that the phase difference between the AD conversion start request signal and the frequency-divided clock (AD synchronization signal) becomes a desired phase difference. Alternatively, specific setting values may be set in advance for one or more of the timer phase register 3232, the AD synchronization phase register 3233, and the frequency dividing phase processing unit 372 (phase adjustment amount) such that the above phase difference becomes a specific phase difference. From the viewpoint of improving the control of the motor 5, the specific phase difference described above is preferably a minimum value in design or implementation.

The setting value of each register or the adjustment amount of the frequency-divided clock may be set by the user via the controller, or may be set via the computer by the user connecting the computer to the semiconductor device. Alternatively, the setting value of each register may be automatically set by the controller or the computer connected to the semiconductor device executing a program.

As described above, according to the second embodiment, the frequency dividing phase processing unit 372 can adjust the phase of the frequency-divided clock obtained by frequency-dividing the common clock on the basis of the AD synchronization phase signal. That is, even in a case where the AD conversion is started in synchronization with the frequency-divided clock, the phase difference between the AD conversion start request signal and the frequency-divided clock becomes constant with respect to the carrier for PWM control regardless of the activation timing of the semiconductor device. Therefore, by using the semiconductor device including the AD converter, it is possible to improve the control accuracy when the information related to the rotation operation of the motor is acquired by the AD converter and the motor is controlled.

In addition, according to the second embodiment, the phase difference between the AD conversion start request signal and the frequency-divided clock can be brought close to a minimum value. As a result, the control accuracy of the motor 5 as control target equipment can be further improved.

Although the invention made by the present inventors has been specifically described based on the embodiments, the present invention is not limited to the embodiments, and it goes without saying that various modifications can be made without departing from the gist of the invention.

For example, in each of the above embodiments, the current sensor provided in the inverter is connected to the AD converter (A), but another sensor may be connected. For example, the AD converter (A) may be provided with a Hall sensor, an encoder, or a resolver provided in the motor. Even in such a case, the control accuracy of the motor can be improved.

In addition, in each of the above embodiments, in a case where the semiconductor device includes a plurality of AD converters, the following can be said. When the AD conversion start request signal synchronized with a periodic carrier is input to at least one of the plurality of AD converters, an aperiodic AD conversion start request signal may be input to another AD converter. Even in such a case, since the possibility of occurrence of noise interference is reduced, the phase difference between the AD conversion start request signal and the AD conversion synchronization signal can be made constant regardless of the activation timing of the semiconductor device, and the control accuracy can be improved.

In addition, for example, in each of the above embodiments, at least some of the elements constituting the semiconductor device may be provided outside the semiconductor device. In this case, the element provided outside the semiconductor device may be configured using another semiconductor, or may be configured by a circuit or the like assembled in a discrete manner.

In addition, for example, in each of the above embodiments, the direct target of the PWM control is the output current of the inverter, and the final control target equipment is a motor driven by the output current. However, the direct target of the PWM control may be equipment/circuit/device or the like different from the inverter. In addition, the final control target may be equipment/circuit/device or the like different from the motor. That is, the direct target of the PWM control and the final control target may be any equipment or the like.

What is claimed is:

1. A semiconductor device comprising: a timer control circuit; and an AD converter that is connected to a sensor that obtains information related to an operation of equipment that is a control target, the semiconductor device generating a PWM control signal for controlling the equipment by using a periodic signal in the timer control circuit based on an output of the AD converter,
wherein the AD converter starts AD conversion in synchronization with a latest AD synchronization signal after receiving an AD conversion start request signal, and
wherein the timer control circuit includes
a phase-locked loop counter that starts counting in association with activation of the semiconductor device, a timer phase register, and an AD synchronization phase register,
executes
processing of outputting a timer phase signal that is a basis for starting generation of the periodic signal and the AD conversion start request signal at a timing when a counter value of the phase-locked loop counter matches a setting value of the timer phase register, and
processing of outputting an AD synchronization phase signal that is a basis for starting generation of the AD synchronization signal at a timing when the counter value of the phase-locked loop counter matches a setting value of the AD synchronization phase register, and
performs control so that a phase difference between the AD conversion start request signal and the AD synchronization signal is constant regardless of a timing of the activation of the semiconductor device.

2. The semiconductor device according to claim 1,
wherein the timer control circuit includes
a timer counter,
causes the timer counter to start counting in response to an output of the timer phase signal, and
generates the periodic signal and the AD conversion start request signal based on a counter value of the timer counter.

3. The semiconductor device according to claim 2,
wherein the timer control circuit starts generation of the AD synchronization signal corresponding to a specific phase in the periodic signal in response to an output of the AD synchronization phase signal.

4. The semiconductor device according to claim 3, comprising:
a plurality of AD converters,
wherein at least one of the plurality of AD converters starts AD conversion in synchronization with the AD synchronization signal after receiving an aperiodic AD conversion start request signal.

5. The semiconductor device according to claim 3,
wherein the PWM control signal is used for PWM control of an output of an inverter, and
wherein the AD converter is connected to a sensor that obtains information related to an operation of the equipment driven by the output of the inverter.

6. The semiconductor device according to claim 5,
wherein feedback control of the equipment is performed by performing the PWM control based on an output of the AD converter.

7. The semiconductor device according to claim 6,
wherein at least one of the timer phase register and the AD synchronization phase register is configured such that a desired setting value is set such that a phase difference between the AD conversion start request signal and the AD synchronization signal becomes a desired phase difference.

8. The semiconductor device according to claim 6,
wherein in at least one of the timer phase register and the AD synchronization phase register, a specific setting value is set in advance such that a phase difference between the AD conversion start request signal and the AD synchronization signal becomes a specific phase difference.

9. The semiconductor device according to claim 6, comprising:
a plurality of AD converters that are respectively connected to a plurality of sensors,
wherein the equipment is a motor, and
wherein the plurality of sensors includes at least one of a sensor that detects a rotation position of the motor, a sensor that detects a rotation speed of the motor, a sensor that detects a temperature of the inverter or an ambient temperature of the inverter, and a sensor that detects an output current of the inverter.

10. The semiconductor device according to claim 3, comprising:
a frequency dividing circuit that starts generation of a frequency-divided clock obtained by frequency-dividing a common clock that is synchronized with a specific phase in the periodic signal and input to the semiconductor device according to an output of the AD synchronization phase signal,
wherein the AD synchronization signal operates in synchronization with the frequency-divided clock.

11. The semiconductor device according to claim 10, comprising:
a plurality of AD converters,
wherein at least one of the plurality of AD converters starts AD conversion in synchronization with the AD synchronization signal after receiving an aperiodic AD conversion start request signal.

12. The semiconductor device according to claim 10,
wherein the PWM control signal is used for PWM control of an output of an inverter, and
wherein the AD converter is connected to a sensor that obtains information related to an operation of the equipment driven by the output of the inverter.

13. The semiconductor device according to claim 12,
wherein feedback control of the equipment is performed by performing the PWM control based on an output of the AD converter.

14. The semiconductor device according to claim 13, comprising:
a frequency dividing phase processing unit that adjusts a phase of the frequency-divided clock,
wherein at least one of phase adjustment amounts of the timer phase register, the AD synchronization phase register, and the frequency dividing phase processing unit is configured such that a desired setting value is set such that a phase difference between the AD conversion start request signal and the AD synchronization signal becomes a desired phase difference.

15. The semiconductor device according to claim 13, comprising:
a frequency dividing phase processing unit that adjusts a phase of the frequency-divided clock,
wherein in at least one of phase adjustment amounts of the timer phase register, the AD synchronization phase register, and the frequency dividing phase processing unit, a specific setting value is set in advance such that a phase difference between the AD conversion start request signal and the AD synchronization signal becomes a specific phase difference.

16. The semiconductor device according to claim 13, comprising:
a plurality of AD converters that are connected to a plurality of sensors,
wherein the equipment is a motor, and
wherein the plurality of sensors includes at least one of a sensor that detects a rotation position of the motor, a sensor that detects a rotation speed of the motor, a sensor that detects a temperature of the inverter or an ambient temperature of the inverter, and a sensor that detects an output current of the inverter.

17. A motor control system comprising:
a controller;
a semiconductor device;
an inverter; and
a motor,
wherein the controller inputs instruction information related to an operation of the motor to the semiconductor device,
wherein the semiconductor device includes a timer control circuit, and an AD converter that is connected to a sensor that obtains information related to the operation of motor, and generates a PWM control signal for controlling the motor by using a periodic signal in the timer control circuit based on the instruction information and an output of the AD converter,
wherein the AD converter starts AD conversion in synchronization with a latest AD synchronization signal after receiving an AD conversion start request signal,
wherein an output of the inverter is controlled based on the PWM control signal,
wherein the motor is driven by an output of the inverter, and
wherein the timer control circuit includes
a phase-locked loop counter that starts counting in association with activation of the semiconductor device, a timer phase register, and an AD synchronization phase register,
executes
processing of outputting a timer phase signal that is a basis for starting generation of the periodic signal and the AD conversion start request signal at a timing when a counter value of the phase-locked loop counter matches a setting value of the timer phase register, and
processing of outputting an AD synchronization phase signal that is a basis for starting generation of the AD synchronization signal at a timing when the counter value of the phase-locked loop counter matches a setting value of the AD synchronization phase register, and
performs control so that a phase difference between the AD conversion start request signal and the AD synchronization signal is constant regardless of a timing of the activation of the semiconductor device.
